(19) United States
(12) Patent Application Publication
(10) Pub. No.: US 2008/0298408 A1
(43) Pub. Date: Dec. 4, 2008

(54) SUBSTRATE FOR OPTICAL SEMICONDUCTOR

(75) Inventors: Takao SHIRAI, Yokohama-shi (JP); Miho Nakamura, Yokohama-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA MATERIALS CO., LTD.

(21) Appl. No.: 12/180,864

(22) Filed: Jul. 28, 2008

Related U.S. Application Data
(63) Continuation of application No. 10/547,697, filed on Sep. 2, 2005.

(30) Foreign Application Priority Data
Sep. 22, 2003 (JP) 2003-329563

(51) Int. Cl. H01S 5/022; H01L 21/02

(52) U.S. Cl. 372/44.01; 438/26; 257/E21.002

(57) ABSTRACT

A substrate for optical semiconductors of the present invention comprises an insulating ceramic substrate, a metal layer provided on the insulating ceramic substrate, a solder layer provided on the metal layer and composed of Sn only or 50 wt % or more of Sn and the balance substantially of Au, and a protective layer provided on the solder layer and composed of Au or Ag having a thickness of 0.01 μm or more and 1 μm or less. The substrate for optical semiconductors as described above makes it possible to reduce stress placed on the optical semiconductor, to suppress development of crystal defects, and to prolong its life when joining the optical semiconductor easily developing crystal defects by slight stress or when in use thereafter.

### CROSS-REFERENCE TO RELATED APPLICATIONS

The present application is a Continuation of U.S. application Ser. No. 10/547,697, filed Sep. 2, 2004, which is based upon PCT National Stage Application No. PCT/JP2004/013766 filed Sep. 21, 2004, and claims the benefit of priority from prior Japanese Patent Application No. 2003-329563, filed Sep. 22, 2003, and the entire contents of each of these applications are incorporated herein by reference.

### TECHNICAL FIELD

The present invention relates to an substrate used for mounting an optical semiconductor, especially excellent in joining ability to an optical semiconductor, possible to relax a stress added to an optical semiconductor at the time of joining to an optical semiconductor or while in use, to reduce damage of an optical semiconductor damaged by even slight stress, and to prolong its life.

### BACKGROUND ART

A substrate for optical semiconductors is used as a semiconductor laser device by mounting an optical semiconductor such as an optical pick up LD for CD (Compact Disc) or DVD (Digital Video Disk). FIG. 1 shows an example of a semiconductor laser device configuration.

A semiconductor laser device 1 has a structure in which an optical semiconductor 2 such as a laser diode is mounted on a substrate 3 for optical semiconductors. The substrate 3 is used to improve heat radiation characteristics, positioning, and the like of the optical semiconductor 2. A heat sink 4 made of copper or the like which is good in heat conductivity is joined on the other surface of the substrate 3 to effectively release heat generated in the optical semiconductor 2 to the outside (refer to, for instance, Patent Document 1).

The substrate 3 for optical semiconductors comprises, for instance, an insulating ceramic substrate 5, a metal layer 6 formed thereon by a sputtering method or the like, and a solder layer 7 formed on the metal layer 6, and the optical semiconductor 2 is joined on the substrate 3 using the solder layer 7 (for instance, refer to Patent Document 2).

FIG. 2 shows a typical relation between current and light output of the optical semiconductor 2. Natural emission light is emitted until the light output reaches Pth, and when it exceeds Pth, laser oscillation (induced emission) occurs. The magnitude of the current at the time of starting this laser oscillation is a threshold current Ith, and more particularly, the current at the point where extension of a straight line of current in an oscillation state vs light output intersects the X axis can be the threshold current Ith. The magnitude of the current in the forward direction when a prescribed light output Po is obtained is an operating current Iop.

In general, different from a silicon chip used to a transistor or the like, the optical semiconductor 2 develops crystal defects due to a slight stress at the time of joining to the substrate 3 for optical semiconductors or when in use. When crystals of the optical semiconductor 2 are well-ordered, induced emission occurs due to emission recombination, so that prescribed light output Po can be obtained for a long period by adding the operating current Iop to the optical semiconductor 2. On the contrary, if there is even a slight crystal defect in the optical semiconductor 2, non-emission recombination occurs at that portion and a lot of heat is generated without emission of light. The crystal defects are further developed in the optical semiconductor 2 due to the heat, and non-emission recombination occurs. Through repetition of this process, the optical semiconductor 2 becomes unable to obtain the prescribed light output Po in a short time, and finally emission of light is stopped.

A concrete explanation will be made on damage caused by stress. A typical transistor or the like in which, for instance, a silicon chip is joined on an alumina substrate has a thermal expansion coefficient of alumina of about 7×10⁻⁶/° C. and a thermal expansion coefficient of the silicon chip of about 3×10⁻⁶/° C. However, despite a big difference in thermal expansion coefficient, it is usable without being damaged. In addition, among transistors made by joining a silicon chip on a lead frame made of copper, the lead frame made of copper is about 17×10⁻⁶/° C., showing a great difference between the thermal expansion coefficients.

On the contrary, a typical semiconductor laser device 1, which is, for instance, made by joining a laser diode on a silicon substrate, has a thermal expansion coefficient in the silicon substrate side of about 3×10⁻⁶/° C. and a thermal expansion coefficient in the optical semiconductor side of about 4.2×10⁻⁶/° C. Though the difference between these thermal expansion coefficients is small and it generates a slight stress, crystal defects are developed in the laser diode due to that stress, shortening its life. Even when an aluminum nitride substrate whose thermal expansion coefficient is about 4.6×10⁻⁶/° C., nearly equal to the thermal expansion coefficient of the laser diode, is used, crystal defects are sometimes developed in the laser diode by stress generated due to this slight difference in thermal expansion coefficient, shortening its life.

Especially, in recent years, high intensity output of an optical semiconductor 2 has been achieved to improve performance of devices. However, this generates a large quantity of heat due to excessive light density on the end face of the optical semiconductor 2, easily causing damage due to its excessive stress, and avoidance of such damage has been an important problem.

Patent Document 1: Japanese Patent Laid-open Application No. Hei 6-37403 (FIG. 11 etc.)

Patent Document 2: Japanese Patent Laid-open Application No. 2002-100826

### DISCLOSURE OF THE INVENTION

As described above, an optical semiconductor develops crystal defects even under slight stress and its life is shortened. Accordingly, a substrate for mounting the optical semiconductor is required to put less stress on the optical semiconductor when the substrate is joined to the optical semiconductor or when in use thereafter, and to be unlikely to develop crystal defects in the optical semiconductor. The present invention has been achieved to solve such a problem, and its object is to provide a substrate for optical semiconductor which enables it to reduce stress put on an optical semiconductor when joined to the optical semiconductor or when in use thereafter, to suppress development of crystal defects of the optical semiconductor and to prolong its life.

As a result of pursuing the research on a substrate for optical semiconductors to suppress development of crystal defects which shortens the life of the optical semiconductor, the present inventors have found that though conventional typical Au (gold)-Sn (tin) solder can be satisfactorily used for joining an article such as a silicon chip which is not easily damaged even when some stress is added, since it is too hard for joining an article such as an optical semiconductor which develops crystal defects under slight stress shortening its life, it cannot sufficiently relax the stress generated during joining of an optical semiconductor or when in use so that crystal defects are developed in the optical semiconductor, shortening its life.

Then, the present inventors have studied materials and composition of a solder constituting a solder layer of a substrate for optical semiconductors. As a result, it is found that the typical Au—Sn solder contains so much Au of 80 wt %, which makes itself stiff, and that is the reason why it cannot sufficiently relax stress generated at the time of joining an optical semiconductor or when in use and develops crystal defects in the optical semiconductor to shorten its life. Then, as a result of increasing Sn content in the Au—Sn solder, it is found that the hardness of the Au—Sn solder can be effectively reduced.

However, when an Au—Sn solder with high Sn content is used as a solder layer, soldering ability is found to be lowered. In manufacturing a semiconductor laser device, reduction of the time period for joining an optical semiconductor to a substrate for optical semiconductors is required to improve productivity, and such a lowering of soldering ability is an obstacle to improvement in productivity. Furthermore, it is found that when the soldering ability is lowered, thermal resistance becomes high and thermal transfer from an optical semiconductor to a substrate is insufficient, which generates stress causing crystal defects in the optical semiconductor, thereby shortening its life.

As a result of repeated study of the deterioration of soldering ability, the inventors have found that the deterioration of soldering ability is due to lowering of wettability caused by an oxide film formed on the surface of an Au—Sn solder which is a solder layer, and further found that formation of the oxide film is due to the high content of easily oxidized Sn in the Au—Sn solder forming the solder layer.

As a result of a study to improve deterioration of the soldering ability due to formation of such an oxide film, the present inventors have found it effective to cover the surface of an Au—Sn solder, being a solder layer, with a non-oxidizing material which will not exert a negative influence on other materials, and to form a protective layer composed of Au (gold) or Ag (silver) (hereinafter merely referred to as a protective layer) as such a material on the surface. In other words, it is found that since Au and Ag are not oxidized, are low in electric resistance, can form a eutectic with Sn which is a component of the solder layer, and do not easily exert a negative influence, they are suitable for formation of a protective layer covering the surf ace of the Au—Sn solder being a solder layer. Furthermore, it is also found that by forming such a protective layer on the surface of the solder layer, Au is not necessarily contained in the solder layer.

Additionally, study of influence of the thickness of a protective layer on the surface oxidation and soldering ability of a solder layer reveals that the surface oxidation and soldering ability of the solder layer are rapidly changed depending on its thickness. That is, when the thickness of the protective layer is less than 0.01 μm, a portion of insufficiently covered solder layer is created, making the joining of the optical semiconductor difficult due to an oxide film created by oxidation of this portion. When the optical semiconductor is joined, thermal resistance of this portion becomes high, generating stress and causing crystal defects in the optical semiconductor, thus shortening its life.

It is found that on the contrary, when the thickness of the protective layer exceeds 1 μm, since the protective layer and the solder layer do not mix completely at the time of heat treatment for joining the optical semiconductor, the protective layer is left as it is, and development of a portion having high concentration of Au or Ag makes joining of the optical semiconductor difficult, and after joining, since the portion having high concentration of Au or Ag is rigid, stress relaxation is insufficient, thereby developing crystal defects in the optical semiconductor, shortening its life.

The present inventors have accomplished the present invention based on the above-described knowledge and information. That is, a substrate for an optical semiconductor of the present invention comprises an insulating ceramic substrate, a metal layer provided on the insulating ceramic substrate, a solder layer provided on the metal layer and composed of Sn only or 50 wt % or more of Sn and the balance substantially of Au, and a protective layer provided on the solder layer and composed of Au or Ag having a thickness of 0.01 μm or more and 1 μm or less.

### BRIEF DESCRIPTION OF THE DRAWINGS

FIG. 1 is a sectional view showing an example of a typical semiconductor laser device.

FIG. 2 is a view showing a relation between current and light output characteristics of the typical semiconductor laser device.

FIG. 3 is a sectional view showing an example of a substrate for an optical semiconductor of the present invention.

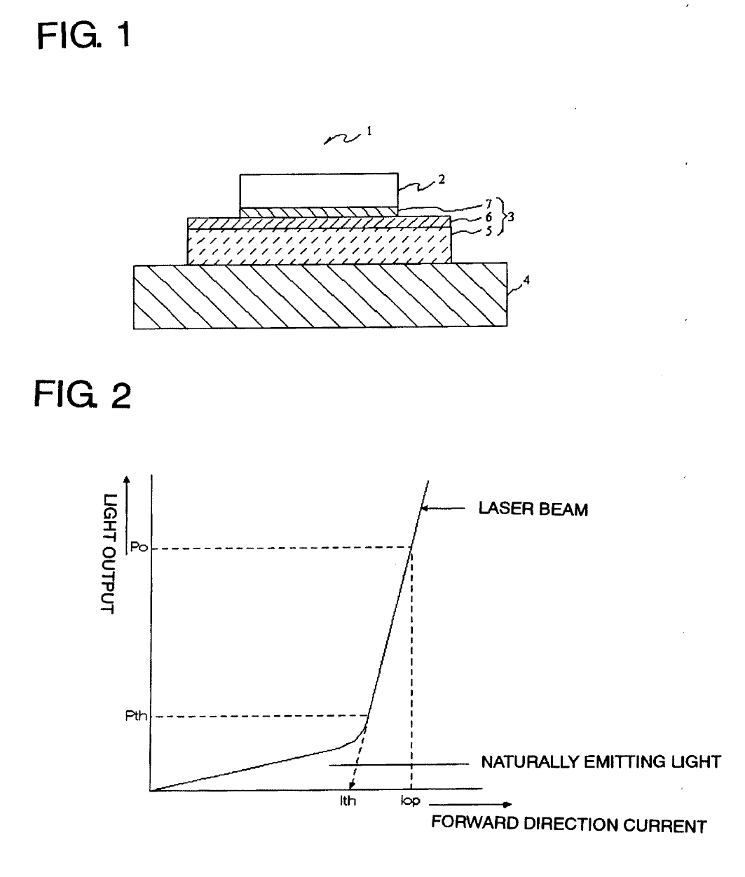

### BEST MODE FOR CARRYING OUT THE INVENTION

Hereinafter, an embodiment of the present invention will be explained.

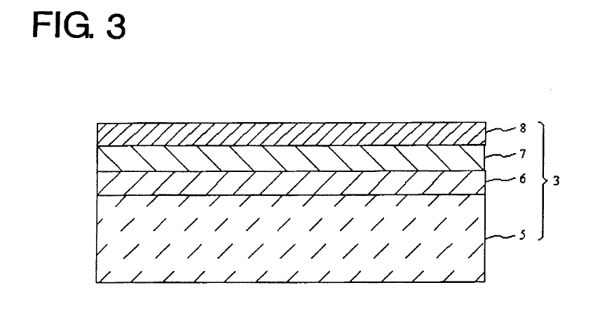

FIG. 3 is a sectional view showing a structure of a substrate 3 for optical semiconductors of the present invention. The substrate 3 for optical semiconductors of the present invention includes a metal layer 6, a solder layer 7, and a protective layer 8 made of Au (gold) or Ag (silver), formed on an insulating ceramic substrate 5 in this order.

The insulating ceramic substrate 5 used in the present invention contains one kind selected from, for instance, aluminum nitride, silicon nitride, silicon carbide, beryllium oxide and diamond as a main component. Thermal conductivity of the insulating ceramic substrate 5 is preferably 80 W/m·K or more, and more preferably 190 W/m·K or more from the point of view of improving heat radiation characteristics, reducing generation of stress, and suppressing development of crystal defects in an optical semiconductor when an optical semiconductor such as a laser diode or the like is mounted.

The thickness of the insulating ceramic substrate 5 is not particularly limited, and can be appropriately adjusted in consideration of its thermal conductivity, strength, and the like. It is preferable to adjust the thickness, for instance, to be in the range of 0.1 mm to 1.5 mm.

When the thermal conductivity of the insulating ceramic substrate 5 is K(W/m·K), and the thickness of the insulating ceramic substrate 5 is t (mm), the ratio (K/t) is preferably 700 or more from a relation with thermal conductivity. In other words, it becomes possible to further improve heat radiation characteristics of the substrate 3 for optical semiconductors by making the thermal conductivity K high and the thickness t thin.

For instance, when an aluminum nitride substrate of 200 W/m·K in thermal conductivity is used, the thickness t is preferably 0.286 mm or less, and when an aluminum nitride substrate of 170 W/m·K in thermal conductivity is used, the thickness t is preferably 0.243 mm or less.

Such an insulating ceramic substrate 5 is obtained, for instance, by adding a sintering auxiliary to a raw material powder such as aluminum nitride and the like as described above, and by forming it into a prescribed substrate shape after adding a binder and the like and mixing, and by sintering the formed product. Various metal compounds can be used as the sintering auxiliary, but rare-earth oxides can be suitably used.

As rare-earth oxides, for instance, Y₂O₃ (yttrium oxide), Er₂O₃ (erbium oxide), Yb₂O₃ (ytterbium oxide), and the like can be cited, and among them, Y₂O₃ is especially suitable for use.

In addition, it is possible to use oxides of alkaline earth metal elements such as Ca, Ba, Sr, and the like, silicon compounds such as SiO₂, Si₃N₄, and the like, and boron compounds such as B₂O₃, B₄C, TiB₂, LaB₆, etc. can be used together other than the rare-earth oxides. Note that, rare-earth oxides, alkaline earth metal oxides and the like can be combined as carbonate, oxalate, nitrate, fluoride etc. which become oxides at the time of sintering.

When a sintered body has transparency similarly to, for example, aluminum nitride, coloring materials such as W, Ti, Zr, Hf, Cr, Mo, Sr, etc. may be added to suppress change of characteristics due to repeated reflection of laser beam.

In this case, the coloring material is preferably added at a rate of 5.0 wt % or less to aluminum nitride raw material powders or the like. When an amount of addition of the coloring materials is too much of exceeding 5.0 wt %, thermal conductivity of the sintered body is more likely to be lowered, and the heat radiation characteristics of the substrate 3 for optical semiconductor deteriorate.

As a concrete method to add the above-described coloring material, it is preferable for it to be added and contained as a form of oxide, nitride, and fluoride of the above-described respective elements, and is preferable that the form is arbitrarily selected considering influence on the characteristics such as heat radiation characteristics, strength, or the like of the insulating ceramic substrate 5

The metal layer 6 is provided on the above-described insulating ceramic substrate 5. The metal layer 6 is layered in the order of, for instance, Ti layer, Pt layer, Au layer from the insulating ceramic substrate 5 side. A circuit may or may not be formed on the metal layer 6. The total thickness of the metal layer 6 consisting of the Ti layer, the Pt layer and the Au layer is preferably 3 μm or less.

Formation of the Ti layer, the Pt layer and the Au layer on the insulating ceramic substrate 5 is preferably performed by applying a thin-film formation of a PVD (Physical Vapor Deposition) method such as a sputtering method, a vacuum vapor deposition method, a molecular beam epitaxy (MBE) method, an ion plating method, and a laser deposition method, etc., and according to circumstances, a CVD (Chemical Vapor Deposition method) method such as a thermal CVD method, a plasma CVD method, a photo CVD method, etc.

The solder layer 7 is formed on the metal layer 6. The solder layer 7 is made of Sn only, or an Au—Sn alloy or mixture containing 50 wt % or more of Sn, the reminder being substantially Au.

By allowing the solder layer 7 to contain Sn at a content of 50 wt % or more, it is possible to effectively reduce the hardness of the solder layer 7. Thereby, it becomes possible to sufficiently relax stress generated mainly due to a difference in thermal expansion coefficient between the insulating ceramic substrate 5 and an optical semiconductor at the time of joining the optical semiconductor or when in use thereafter, and to suppress development of crystal defects in the optical semiconductor in which crystal defects are developed even by slight stress, shortening its life as a result, so as to prolong the life thereof.

The solder layer 7 is preferably made of Sn only, or a substance containing 60 wt % or more of Sn, the reminder being substantially Au, and is more preferably made of Sn only, or a substance containing 70 wt % or more of Sn, the reminder being substantially Au. The melting point of the solder layer 7 is preferably between 210° C. and 500° C., and more preferably between 210° C. and 400° C.

By increasing the Sn content as above, it is possible to further effectively reduce the hardness of the solder layer 7, to sufficiently relax stress exerted on an optical semiconductor when joining the optical semiconductor or when in use thereafter, and to suppress development of crystal defects in the optical semiconductor in which the crystal defect is developed even by slight stress, shortening its life as a result, so as to prolong the life thereof.

Formation of the solder layer 7 on the metal layer 6 can be performed by a method of, for instance, vapor deposition of Au and Sn, or sputtering, etc., or by a method of applying a solder paste having a composition such as described above with a screen printing or the like. The thickness of the solder layer 7 is preferably 2 μm or more and 5 μm or less.

The solder layer 7 of 2 μm or less in thickness is too thin, which fails sufficient relaxation of the stress generated due to a difference in thermal expansion coefficient of the optical semiconductor and the insulating ceramic substrate 5, and may cause a difficulty in suppression of development of crystal defects in the optical semiconductor for prolongation of the life thereof. About 5 μm of the thickness of the solder layer 7 is sufficient to obtain a relaxation effect, and provision of the solder layer thicker than that is undesirable from a point of productivity or the like, and not agreeable because it may lower the effect to suppress development of crystal defects in the optical semiconductor shortening its life.

The protective layer 8 made of Au or Ag (merely referred to as a protective layer) is formed on the above-described solder layer 7. The protective layer 8 is provided to avoid formation of an oxidized layer on the surface of the solder layer 7. In order to make stress exerted on an optical semiconductor as little as possible when joining the optical semiconductor or when in use thereafter, to suppress development of crystal defects, and to prolong its life, the solder layer 7 of the present invention is designed to reduce the hardness thereof by containing 50 wt % or more of Sn.

However, since the content of easily oxidizable Sn is large, an oxide film is easily formed on the surface thereof. The oxide film lowers solder wettability, making joining of an optical semiconductor difficult, and disturbs thermal transfer from an optical semiconductor to the insulating ceramic substrate 5 due to high thermal resistance after joining of an optical semiconductor, and develops crystal defects in the optical semiconductor, shortening the life thereof.

Accordingly, in the present invention, the protective layer 8 made of Au or Ag is provided as a substance to prevent formation of an oxide film in such a solder layer 7. Since this protective layer 8 is made of Au or Ag, which are both metals not easily oxidized, it can suppress formation of an oxide film in the solder layer where the above-described oxide film easily forms, and can restrain lowering of solder wettability. In addition, since Au or Ag which makes the protective layer 8 can form a eutectic with Sn which is a constituent of the solder layer, it easily mixes with the solder layer 7 at the time of joining the optical semiconductor, and does not easily generate a negative influence.

The thickness of such a protective layer 8 is in the range of 0.01 μm to 1 μm. When the thickness of the protective layer 8 is less than 0.01 μm, a portion where the surface of the solder layer 7 is not sufficiently covered with the protective layer 8 is created, and joining of the optical semiconductor is made difficult because this uncovered portion is oxidized into an oxide film. In addition, after the optical semiconductor is joined, thermal transfer from the optical semiconductor to the insulating ceramic substrate 5 is disturbed due to high thermal resistance of this oxide film, which results in development of crystal defects in the optical semiconductor to shorten the life.

When the thickness of the protective layer 8 exceeds 1 μm, the protective layer 8 and the solder layer 7 do not mix sufficiently with each other, leaving the protective layer 8 as it is at the time of heat treatment for joining the optical semiconductor, and a portion having a high concentration of Au or Ag may be created, which makes joining of the optical semiconductor difficult. After joining of the optical semiconductor, since portions where such a protective layer 8 remains, or where concentration of Au or Ag is high, are rigid, stress is not sufficiently relaxed, causing development of crystal defects in the optical semiconductor and shortening its life.

The thickness of the protective layer 8 is preferably 0.01 μm or more and 0.2 μm or less. By making the thickness of the protective layer 8 be 0.2 μm or less, the protective layer 8 and the solder layer 7 can be easily mixed together at the time of heat treatment for joining the optical semiconductor, partial elevation of the concentration of Au or Ag can be controlled, and development of crystal defects in the optical semiconductor can be suppressed and its life can be prolonged due to sufficient relaxation of the stress.

Such a protective layer 8 made of Au or Ag can be formed by applying a PVD (Physical Vapor Deposition) method such as a sputtering method, a vacuum vapor deposition method, a molecular beam epitaxy (MBE) method, an ion plating method, and a laser deposition method, etc., and according to circumstances, a thin-film formation such as a CVD (Chemical Vapor Deposition) method such as a thermal CVD method, a plasma CVD method, a photo CVD method, etc. or a paste method can be applied.

The substrate 3 for optical semiconductors of the present invention is used as a semiconductor laser device by joining an optical semiconductor. Joining of the optical semiconductor substrate 3 and the optical semiconductor is preferably subjected to heat treatment at a temperature higher than the melting temperature, for instance, from 250° C. to 400° C. for 10 seconds to 5 minutes. The substrate 3 for optical semiconductors of the present invention is suitably used for joining, especially with a high-power type optical semiconductor. When joining a high-power type optical semiconductor, abundant heat is apt to be generated due to excessive optical density at the end_face of the optical semiconductor while in use, and excessive stress is apt to be exerted on the optical semiconductor. This stress develops crystal defects in the optical semiconductor and shortens the life. Therefore, the substrate 3 for optical semiconductors of the present invention can prolong the life longer than ever by joining such a high-power type optical semiconductor.

### EXAMPLES

The present invention will be explained more in detail referring to examples.

Ti, Pt, and Au films are formed in this order on an aluminum nitride substrate of 1.0 mm long, 1.0 mm width, and 0.2 mm thick using a vacuum vapor deposition method to prepare a metal layer having a total thickness of 0.6 μm, and a solder layer made of Sn only, or made of Sn and Au is formed on the metal layer, and an Au layer as a protective layer is further formed on the solder layer using a vacuum vapor deposition method to prepare a substrate for optical semiconductors.

As shown in Table 1, plural kinds of the optical semiconductor substrate are prepared by changing the Au—Sn composition of the solder layer, and by changing the thickness of the Au layer formed on the solder layer in the range of 0.008 to 1.2 μm.

Further, in order to examine the influence by difference in thermal conductivity of the aluminum nitride substrate, a similar experiment on a substrate whose solder layer composition is 10 wt % of Au and 90 wt % of Sn is carried out by changing the thermal conductivity of the aluminum nitride substrate to 70, 170, 200, and 250 (W/m·K).

Furthermore, in order to study the influence by difference in thickness of the solder layer, a substrate having a solder layer composed of Au 10 wt % and Sn 90 wt %, the thermal conductivity of the aluminum nitride substrate being 200 (W/m·K), and the thickness of Au layer being 0.1 μm, is tested by experiments by changing the thickness of the solder layer in the range of 1 μm to 6 μm.

In order to study effectiveness of the Ag layer as a protective layer, a substrate having a composition of the solder layer being Au 10 wt % and Sn 90 wt %, thermal conductivity of the aluminum nitride substrate being 200 (W/m·K), and the thickness of the solder layer being 3 μm is examined by changing the thickness of the Ag layer as a protective layer.

Note that the substrates with a mark “*” in Table 1 are those within the range of the present invention, and Sn content in the solder layer is 50 wt % or more, the thickness of the Au layer or Ag layer is from 0.01 μm to 1 μm.

Then, a laser diode of 1.0 mm in length, 1.0 mm in width and 0.2 mm in thickness is arranged on this substrate for joining by heat treatment at 400° C. for 1 minute to obtain a semiconductor laser device. In order to examine effects of the composition of the solder layer and thickness and the like of the Au or Ag layer as a protective layer formed on the solder layer, thermal resistance ratio and Iop life are measured. The measurement results of the thermal resistance ratio and the Iop life are shown in Table 1.

The thermal resistance ratio is expressed by measuring thermal resistance for 1 second of pulse period, and by expressing the result in terms of ratio (%) to thermal resistance of a substance having 20 wt % of Au, 80 wt % of Sn and 0.1 μm in thickness of the Au layer being supposed to be 100% as a criterion. The thermal resistance ratio relates to evaluation of soldering ability, and high thermal resistance ratio indicates the existence of a portion where oxidation occurs on the surface of the solder layer or a portion where an Au layer or Ag layer as a protective layer is not completely dissolved in the solder layer.

Measurement of the Iop life is carried out by allowing a semiconductor laser device to emit light in a thermostatic oven at 80° C. while feeding it a current of 30 mA, and by measuring the passage of time till the semiconductor laser device stops emitting. It shows that the longer the Iop life, the more the stress exerted on the laser diode is relaxed, and the more favorably the soldering is performed.

TABLE 1

| | Solder | | | | | Aluminum | | |
|---|---|---|---|---|---|---|---|---|
| | layer | | Solder | | Protective | nitride | Heat | |
| | composition | | layer | Protective | layer | substrate | Resistance | Iop |
| | Au | Sn | thickness | layer | thickness | thermal | rate | life |
| | (wt %) | (wt %) | (μm) | composition | (μm) | conductivity | (%) | (h) |
| | 0 | 100 | 3 | Au | 0.008 | 200 | 120 | 500 |
| * | 0 | 100 | 3 | Au | 0.01 | 200 | 101 | 2000 |
| * | 0 | 100 | 3 | Au | 0.1 | 200 | 100 | 2200 |
| * | 0 | 100 | 3 | Au | 1 | 200 | 101 | 2000 |
| | 0 | 100 | 3 | Au | 1.2 | 200 | 125 | 1000 |
| | 10 | 90 | 3 | Au | 0.008 | 200 | 118 | 800 |
| * | 10 | 90 | 3 | Au | 0.01 | 200 | 102 | 1900 |
| * | 10 | 90 | 1 | Au | 0.1 | 200 | 99 | 1700 |
| * | 10 | 90 | 2 | Au | 0.1 | 200 | 101 | 2000 |
| * | 10 | 90 | 3 | Au | 0.1 | 200 | 101 | 2100 |
| * | 10 | 90 | 4 | Au | 0.1 | 200 | 101 | 2100 |
| * | 10 | 90 | 5 | Au | 0.1 | 200 | 102 | 2100 |
| * | 10 | 90 | 6 | Au | 0.1 | 200 | 103 | 1700 |
| * | 10 | 90 | 3 | Au | 1 | 200 | 101 | 2000 |
| | 10 | 90 | 3 | Au | 1.2 | 200 | 123 | 900 |
| | 10 | 90 | 3 | Ag | 0.008 | 200 | 122 | 900 |
| * | 10 | 90 | 3 | Ag | 0.01 | 200 | 103 | 1900 |
| * | 10 | 90 | 3 | Ag | 0.1 | 200 | 102 | 2000 |
| * | 10 | 90 | 3 | Ag | 1 | 200 | 101 | 1900 |
| | 10 | 90 | 3 | Ag | 1.2 | 200 | 119 | 1000 |
| | 10 | 90 | 3 | Au | 0.008 | 250 | 119 | 800 |
| * | 10 | 90 | 3 | Au | 0.01 | 250 | 96 | 2200 |
| * | 10 | 90 | 3 | Au | 0.1 | 250 | 87 | 2300 |
| * | 10 | 90 | 3 | Au | 1 | 250 | 97 | 2400 |
| | 10 | 90 | 3 | Au | 1.2 | 250 | 112 | 900 |
| | 10 | 90 | 3 | Au | 0.008 | 70 | 112 | 800 |
| * | 10 | 90 | 3 | Au | 0.01 | 70 | 114 | 1200 |
| * | 10 | 90 | 3 | Au | 0.1 | 70 | 111 | 1200 |
| * | 10 | 90 | 3 | Au | 1 | 70 | 114 | 1200 |
| | 10 | 90 | 3 | Au | 1.2 | 70 | 118 | 800 |
| | 10 | 90 | 3 | Au | 0.008 | 170 | 109 | 800 |
| * | 10 | 90 | 3 | Au | 0.01 | 170 | 108 | 1800 |
| * | 10 | 90 | 3 | Au | 0.1 | 170 | 109 | 1800 |
| * | 10 | 90 | 3 | Au | 1 | 170 | 108 | 1700 |
| | 10 | 90 | 3 | Au | 1.2 | 170 | 117 | 800 |

TABLE 2

| | Solder | | | | | Aluminum | | |
|---|---|---|---|---|---|---|---|---|
| | layer | | Solder | | Protective | nitride | Heat | |
| | composition | | layer | Protective | layer | substrate | Resistance | Iop |
| | Au | Sn | thickness | layer | thickness | thermal | rate | life |
| | (wt %) | (wt %) | (μm) | composition | (μm) | conductivity | (%) | (h) |
| | 20 | 80 | 3 | Au | 0.008 | 200 | 121 | 1200 |
| * | 20 | 80 | 3 | Au | 0.01 | 200 | 100 | 2000 |
| * | 20 | 80 | 3 | Au | 0.1 | 200 | 100 | 2000 |
| * | 20 | 80 | 3 | Au | 1 | 200 | 101 | 1900 |
| | 20 | 80 | 3 | Au | 1.2 | 200 | 118 | 1100 |
| | 30 | 70 | 3 | Au | 0.008 | 200 | 123 | 1100 |
| * | 30 | 70 | 3 | Au | 0.01 | 200 | 100 | 1900 |
| * | 30 | 70 | 3 | Au | 0.1 | 200 | 100 | 1900 |
| * | 30 | 70 | 3 | Au | 1 | 200 | 102 | 1800 |
| | 30 | 70 | 3 | Au | 1.2 | 200 | 121 | 1100 |
| | 40 | 60 | 3 | Au | 0.008 | 200 | 102 | 900 |
| * | 40 | 60 | 3 | Au | 0.01 | 200 | 100 | 1700 |
| * | 40 | 60 | 3 | Au | 0.1 | 200 | 100 | 1800 |
| * | 40 | 60 | 3 | Au | 1 | 200 | 101 | 1700 |
| | 40 | 60 | 3 | Au | 1.2 | 200 | 124 | 1200 |
| | 50 | 50 | 3 | Au | 0.008 | 200 | 126 | 700 |
| * | 50 | 50 | 3 | Au | 0.01 | 200 | 101 | 1700 |
| * | 50 | 50 | 3 | Au | 0.1 | 200 | 102 | 1700 |
| * | 50 | 50 | 3 | Au | 1 | 200 | 102 | 1700 |
| | 50 | 50 | 3 | Au | 1.2 | 200 | 119 | 1100 |
| | 60 | 40 | 3 | Au | 0.008 | 200 | 120 | 900 |
| | 60 | 40 | 3 | Au | 0.01 | 200 | 101 | 1200 |
| | 60 | 40 | 3 | Au | 0.1 | 200 | 100 | 1200 |
| | 60 | 40 | 3 | Au | 1 | 200 | 100 | 1200 |
| | 60 | 40 | 3 | Au | 1.2 | 200 | 120 | 1200 |
| | 70 | 30 | 3 | Au | 0.008 | 200 | 114 | 1100 |
| | 70 | 30 | 3 | Au | 0.01 | 200 | 102 | 1200 |
| | 70 | 30 | 3 | Au | 0.1 | 200 | 101 | 1200 |
| | 70 | 30 | 3 | Au | 1 | 200 | 102 | 1200 |
| | 70 | 30 | 3 | Au | 1.2 | 200 | 115 | 1200 |
| | 80 | 20 | 3 | Au | 0.008 | 200 | 121 | 1100 |
| | 80 | 20 | 3 | Au | 0.01 | 200 | 102 | 1200 |
| | 80 | 20 | 3 | Au | 0.1 | 200 | 104 | 1200 |
| | 80 | 20 | 3 | Au | 1 | 200 | 105 | 1200 |
| | 80 | 20 | 3 | Au | 1.2 | 200 | 118 | 1200 |

As is clear from Tables 1 and 2, it is confirmed that the all devices designed to have 50 wt % or more of Sn in the solder layer, and a thickness of the Au layer as a protective layer in the range of 0.01 μm to 1 μm have their Iop lives exceeding 1500 hours, stress exerted on the laser diode is relaxed, and development of crystal defects is suppressed in the laser diode. It is also confirmed that the Iop life can be further improved by making the Sn content in the solder layer 60 wt % or more, preferably 70 wt % or more.

In addition, it is confirmed that those having a thickness of the Au layer as a protective layer from 0.01 μm to 0.2 μm can prolong their Iop lives, and those using an aluminum nitride substrate having thermal conductivity of 80 W/m·K or more, or more preferably 190 W/m·K or more can prolong their Iop lives much longer. And it is also confirmed that the same effect as in the case of the Au layer can be obtained in the case of using the Ag layer as a protective layer.

### INDUSTRIAL APPLICABILITY

The present invention can be applied to a work to manufacture a semiconductor laser device by joining an optical semiconductor.

What is claimed is:

1. A manufacturing method of a semiconductor laser device, comprising:
producing a substrate for an optical semiconductor by forming a metal layer, a solder layer composed of Sn only or 50 wt % or more of Sn and the balance substantially of Au and having a thickness of 2 μm or more and 5 μm or less, and a protective layer composed of Au or Ag and having a thickness of 0.01 μm or more and 1 μm or less in order on an insulating ceramic substrate made of an aluminum nitride substrate having thermal conductivity of 190 W/m·K or more;
arranging a laser diode on the substrate for an optical semiconductor; and
joining the substrate for an optical semiconductor and the laser diode by heat-treating at a temperature from 250° C. to 400° C. for 10 seconds to 5 minutes so as to mix the protective layer with the solder layer.

2. The manufacturing method according to claim 1,
wherein the aluminum nitride substrate has thermal conductivity in a range of 200 W/m·K or more and 250 W/m·K or less.

3. The manufacturing method according to claim 1,
wherein the aluminum nitride substrate has a thickness of 0.1 mm or more and 1.5 mm or less.

4. A semiconductor laser device made by a method comprising:
producing a substrate for an optical semiconductor by forming a metal layer, a solder layer composed of Sn only or 50 wt % or more of Sn and the balance substantially of Au and having a thickness of 2 μm or more and 5 μm or less, and a protective layer composed of Au or Ag and having a thickness of 0.01 μm or more and 1 μm or less in order on an insulating ceramic substrate made of an aluminum nitride substrate having thermal conductivity of 190 W/m·K or more;
arranging a laser diode on the substrate for an optical semiconductor; and
joining the substrate for an optical semiconductor and the laser diode by heat-treating at a temperature from 250° C. to 400° C. for 10 seconds to 5 minutes so as to mix the protective layer with the solder layer.

5. The semiconductor laser device according to claim 4,
wherein the aluminum nitride substrate has thermal conductivity in a range of 200 W/m·K or more and 250 W/m·K or less.

6. The semiconductor laser device according to claim 4,
wherein the aluminum nitride substrate has a thickness of 0.1 mm or more and 1.5 mm or less.

7. A substrate for an optical semiconductor, comprising:
an insulating ceramic substrate;
a metal layer provided on said insulating ceramic substrate;
a solder layer provided on said metal layer and composed of Sn only or 50 wt % or more of Sn and the balance substantially of Au; and
a protective layer provided on the solder layer and composed of Au or Ag having a thickness of 0.01 μm or more and 1 μm or less.

8. A substrate for an optical semiconductor according to claim 7,
wherein said solder layer has a thickness of 2 μm or more and 5 μm or less.

9. A substrate for an optical semiconductor according to claim 7,
wherein said insulating ceramic substrate contains one kind selected from aluminum nitride, silicon nitride, silicon carbide, beryllium oxide and diamond as a main component.

10. A substrate for an optical semiconductor according to claim 9,
wherein said insulating ceramic substrate has thermal conductivity of 80 W/m·K or more.

11. An optical assembly comprising:
the substrate of claim 7; and
a laser diode arranged on the substrate.

12. A semiconductor laser device according to claim 4,
wherein said solder layer has a thickness of 2 μm or more and 5 Mm or less.

13. A semiconductor laser device according to claim 4,
wherein said insulating ceramic substrate contains one kind selected from aluminum nitride, silicon nitride, silicon carbide, beryllium oxide and diamond as a main component.

14. A semiconductor laser device according to claim 13,
wherein said insulating ceramic substrate has thermal conductivity of 80 W/m·K or more.
